(19) United States
(12) Patent Application Publication
(10) Pub. No.: US 2013/0309463 A1
(43) Pub. Date: Nov. 21, 2013

(54) SYNTHETIC PAPER

(71) Applicant: LONGPONT CO., LTD, Shenzhen (CN)

(72) Inventors: Shiyi TAO, Shenzhen (CN); Peizhi HENG, Shenzhen (CN)

(73) Assignee: LONGPONT CO., LTD., Shenzhen (CN)

(21) Appl. No.: 13/952,663

(22) Filed: Jul. 28, 2013

Related U.S. Application Data
(63) Continuation-in-part of application No. PCT/CN2012/000077, filed on Jan. 17, 2012.

(30) Foreign Application Priority Data
Jan. 27, 2011 (CN) 201110029777.7

(51) Int. Cl. H05K 1/03

(52) U.S. Cl. CPC H05K 1/0366
USPC 428/209; 428/339; 162/146

(57) ABSTRACT

Synthetic paper, including: between 10 and 90 wt. % of structural fibers, and between 90 and 10 wt. % of bonding fibers. The structural fibers are poly(p-phenylene telephthalamide) (PPTA) fibers having a fineness of between 1 and 2 d, and a length of between 3 and 10 mm. The bonding fibers are fibrids or a pulp of the PPTA. The structural fibers and the bonding fibers are shaped by a wet-forming papermaking method, and hot rolled to form the synthetic paper.

### CROSS-REFERENCE TO RELATED APPLICATIONS

This application is a continuation-in-part of International Patent Application No. PCT/CN2012/000077 with an international filing date of Jan. 17, 2012, designating the United States, now pending, and further claims priority benefits to Chinese Patent Application No. 201110029777.7 filed Jan. 27, 2011. The contents of all of the aforementioned applications, including any intervening amendments thereto, are incorporated herein by reference. Inquiries from the public to applicants or assignees concerning this document or the related applications should be directed to: Matthias Scholl P. C., Attn.: Dr. Matthias Scholl Esq., 14781 Memorial Drive, Suite 1319, Houston, Tex. 77079.

### BACKGROUND OF THE INVENTION

1. Field of the Invention

The invention relates to synthetic paper.

2. Description of the Related Art

Printed circuit boards (PCBs) are prepared by impregnating a reinforcing agent in an impregnated resin, drying the resin to form a pre-preg, coating copper on the surface of the pre-preg to yield a copper clam laminate (CCL) (also referring to basal lamina), and laminating one or more layers of the CCLS as needed to yield the printed circuit board. The quality of an electronic product is closely related to the performance parameters of the PCB, such as heat resistance, coefficient of thermal expansion (CTE), dielectric constant (Dk), and dielectric loss (Df).

With the increasingly harsh conditions for the process and use of the PCB, higher requirements have been imposed on the heat resistance property of a PCB basal lamina. PCB basal lamina is prepared by sticking copper to an insulating material to form a structural layer. The PCB basal lamina provides the PCB with the electronic and mechanical properties. Most of the insulating materials include reinforcing fibers and organic fibers. A commonly used reinforcing fiber is a glass fiber, which is a high temperature resistant material. Substituted materials include: aramid fibers, acrylic fibers, quartz fibers, and carbon fibers; and polyesters, and vinyl esters, and cyanate ester resins. Polyurethanes and bismaleimide triazine resins (BT) are mainly used in the high temperature field. A commonly used resin is epoxy resins.

The synthetic paper composed of structural fibers of aramid fibers and bonding fibers has properties of high strength, low distortion, high temperature resistance, chemical resistance, excellent insulation, and no fatigue reaction, thereby being widely used.

Typical synthetic paper is prepared by liquid crystal spinning of between 60 and 97 wt. % of a p-aromatic polyamide fibers and between 3 and 40 wt. % of a bonding agent. The bonding agent is a meta-aromatic polyamide fiber. When the synthetic paper is used as a base material for preparing a circuit board, it provides the produced circuit board with properties of high insulation reliability, excellent dimension stability, and strong heat resistance. Compared with other reinforcing materials, the synthetic paper prepared by the method is advantageous in its high modulus, low specific gravity, and low dielectric constant. In papermaking process, short fibers are used as the whole filler. Because the radial expansion of the short fibers, the synthetic paper has a negative axial coefficient of thermal expansion (CTE) value.

When used as the base material for a circuit board substrate, the synthetic paper is required to withstand the heat and pressure during the lamination process. In the production of the synthetic paper, the selection of the bonding fiber largely affects the performance of a resulting synthetic paper. Another typical synthetic paper is prepared by using a resin as the bonding fiber and a para-aramid fiber as the structural fiber. When the impregnated synthetic paper is used as the substrate for preparing the circuit board, the resin will be molten again in the lamination process because the glass transition temperature (Tg) of the resin is much lower than that of the para-aramid fiber, thereby resulting unstable bonding of the synthetic paper and obvious size distortion of the circuit board substrate.

Thus, selections of the bonding fiber and the structural fiber directly affect the performance of the laminated circuit board.

### SUMMARY OF THE INVENTION

In view of the above-described problems, it is one objective of the invention to provide synthetic paper.

It is another objective of the invention to provide a pre-preg.

It is still another objective of the invention to provide a printed circuit board.

To achieve the above objective, in accordance with one embodiment of the invention, there is provided synthetic paper, comprising: structural fibers, the structural fibers comprising a poly(p-phenylene telephthalamide) (PPTA) fibers (also known as para-aramid fibers); and bonding fibers, the bonding fibers comprising fibrids or a pulp of the PPTA (also known as fibrid or pulp of the para-aramid). The synthetic paper is advantageous in that: 1) The bonding fibers employ the fibrid or the pulp of the para-aramid, which is very to defiber, so that the papermaking property and the paper-forming property of the raw materials during the papermaking process are improved. 2) The structural fibers employ the para-aramid fibers. The para-aramid fibers has improved fibrillation, increased surface area, and increased bonding property between the fibers, thereby improving the strength of the synthetic paper. 3) The synthetic paper has a superior heat resistant property than other adhesives. Thus, when used as a base material for a circuit board substrate, it provides the circuit board with excellent performance of heat resistance and pressure resistance, because the base material is capable of withstanding the high temperature and high pressure during the lamination process.

In a class of this embodiment, the synthetic paper comprises: between 10 and 90 wt. % of the structural fibers, and between 90 and 10 wt. % of the bonding fibers. Preferably, the synthetic paper comprises: between 70 and 90 wt. % of the structural fibers, and between 10 and 30 wt. % of the bonding fibers; between 70 and 80 wt. % of the structural fibers, and between 20 and 30 wt. % of the bonding fibers; 80% of the structural fibers, and 20% of the bonding fibers; or 70% of the structural fibers, and 30% of the bonding fibers.

In accordance with another embodiment of the invention, there is provided with a pre-preg being prepared by employing the synthetic paper as the base material, and impregnating the base material in an impregnating material to produce the pre-preg. The pre-preg is used as the circuit board substrate.

In a class of this embodiment, the pre-preg is prepared by employing the synthetic paper as the base material, and impregnating the base material in an impregnating material to produce the pre-preg. The impregnating material is selected from an epoxy resin, a polyimide resin, and a polytetrafluoroethylene (PTFE) resin. Preferably, the impregnating material is the polytetrafluoroethylene resin; and a weight ratio between the impregnating material and the synthetic paper is between 47% and 55%.

In a class of this embodiment, the pre-preg has a linear coefficient of thermal expansion relative to X and Y axes in a plane of between 4 and 9 ppm/° C., a dielectric constant of between 2.4 and 3.5, and a dielectric loss of between 0.001 and 0.013.

In accordance with still another embodiment of the invention, there is provided with a printed circuit board. The printed circuit board is prepared by coating copper on the pre-preg to produce a copper clad laminate, and further processing the copper clad laminate to produce the printed circuit board.

Advantages of the circuit board substrate (herein referring to the pre-preg) and the printed circuit board of the invention are summarized as follows:
1) Light weight.
2) High temperature resistant property. The para-aramid is capable of withstanding a temperature of 500° C., thereby meeting different application environments of the circuit board.
3) Low dielectric constant (Dk). The Dk value of the printed circuit board directly influences the transmission speed of high-frequency signals, the formula of the transmission speed of signals is

$$v = k \cdot \frac{c}{\sqrt{ɛ}} ,$$

in which ν represents the transmission speed of signals, κ represents a constant, c represents the light speed in the vacuum, and ∈ represents the dielectric constant. The dielectric constant of the glass fiber is 6.6. The dielectric constant of a circuit board substrate prepared by epoxy resin-impregnated glass fiber is between 4.5 and 4.7. The dielectric constant of a circuit board substrate prepared by epoxy resin-impregnated synthetic paper is between 3.4 and 3.5. The dielectric constant of a circuit board substrate prepared by polyimide resin-impregnated synthetic paper is less than 3.5. The dielectric constant of a circuit board substrate prepared by PTFE resin-impregnated synthetic paper is between 2.4 and 2.8. Thus, the printed circuit board using the synthetic paper of the invention as the reinforcing material is capable of largely improving the transmission speed of signals, which is very significant for the popularization of the printed circuit board.
4) Low dielectric loss (Df). The circuit board substrate made of glass fiber has a Df of between 0.015 and 0.02; the Df of the circuit board substrate prepared by the PTFE resin-impregnated synthetic paper does not exceed 0.002.
5) The circuit board substrate made of the synthetic paper can be perforated by laser, and has a good processing performance.
6) The circuit board substrate of the invention is capable of withstanding cycled thermal shock for exceeding 10 thousand times (international standard being 4800 times), so that it can be widely used in the aerospace engines.
7) Good thermal stability. The Circuit board substrate made of the synthetic paper has the linear coefficient of thermal expansion relative to X and Y axes in a plane of between 4 and 9 ppm/° C., so that it is can be extensively used for IC packing.

### DETAILED DESCRIPTION OF THE EMBODIMENTS

For further illustrating the invention, experiments detailing synthetic paper, and a pre-preg, a copper clad laminate, and a printed circuit board comprising the same are described below. It should be noted that the following examples are intended to describe and not to limit the invention.

Raw materials for preparing synthetic paper comprise:

A para-aramid fiber: a poly(p-phenylene telephthalamide) (PPTA) fiber, produced by Teijin Lid., Japan, trade name: Twaron®1080.

A fibrid of para-aramid: a fibrid of the PPTA, produced by Teijin Lid., Japan, trade name: Twaron®8016.

A pulp of para-aramid: a pulp of the PPTA, produced by Teijin Lid., Japan, trade name: Twaron®1094.

Performance measurements of the synthetic paper were carried out from the following aspects according to corresponding national standards:

| | |
|---|---|
| mass | GB/T 451.3-2002 |
| thickness | GB/T 451.3-2002 |
| density | GB/T 451.3-2002 |
| tensile strength | GB/T 453-2002 |
| percentage elongation | GB/T 453-2002 |
| tear strength | GB/T 455-2002 |

### Example 1

Synthetic paper was prepared by raw materials comprising 80 parts (herein “part” referring to “weight part”) of the para-aramid fiber (5-6 mm), and 20 parts of the fibrid of para-aramid.

80 parts of the para-aramid fibers was collected to prepare a first solution comprising 1 wt. % of the para-aramid fibers. The first solution was defibered by using a defibering machine to produce a pulp A. 20 parts of the fibrid of para-aramid was collected to prepare a second solution comprising 2 wt. % of the fibrid of para-aramid The second solution was defibered by using a hydraulic pulper, milled, and beaten, during which the beating degree was controlled at 75° SR, to produce a pulp B. The pulp A and the pulp B were evenly mixed in a pool to produce a papermaking pulp. 5 parts of a polyethylene oxide was added to a pressure stabilizing box. A pressure head was adjusted by the pressure stabilizing box so as to evenly distribute the papermaking pulp to a paper-forming mesh and allow a superfluous pulp to overflow to a white pool. When the papermaking pulp flowed along the paper-forming mesh, water was separated from the papermaking pulp under the force of a couch roll. A resulting wet paper sheet was transferred from the paper-forming mesh to a woolen blanket, and dehydrated in a vacuum box by wet pressing, and was further dried in a dryer. A paper sheet was then hot rolled by a hot mill. The hot mill was provided with two hot rolling lines of different temperature and pressure. A first hot rolling line had a pressure of 25 kg/cm, a surface temperature of a first roller of 250° C., and a rolling speed of 15 m/min. A second hot rolling line had a pressure of 100 kg/cm, a surface temperature of a second roller of 220° C., and a rolling speed of 15 m/min. After being hot rolled, the paper sheet was finished by a calender, a temperature of which was controlled at 180° C. Mechanical properties of the synthetic paper are shown in Table 1.

TABLE 1
Mechanical properties of synthetic paper

| Mechanical property | unit | result |
|---|---|---|
| Mass | g/m² | 34.30 |
| Thickness | mm | 0.049 |
| Density | g/cm³ | 0.70 |
| Tensile strength | KN/m MD | 1.12 |
| Percentage elongation | % MD | 2.6 |

### Example 2

Synthetic paper was prepared by raw materials comprising 20 parts of the para-aramid fiber (5-6 mm), and 80 parts of the fibrid of para-aramid.

Herein the amounts of the ingredients were adjusted, but the preparation method of the synthetic paper is the same as that in Example 1. Mechanical properties of the synthetic paper are shown in Table 2.

TABLE 2
Mechanical properties of synthetic paper

| Mechanical property | unit | result |
|---|---|---|
| Mass | g/m² | 34.90 |
| Thickness | mm | 0.045 |
| Density | g/cm³ | 0.78 |
| Tensile strength | KN/m MD | 1.86 |
| Percentage elongation | % MD | 2.25 |

### Example 3

Synthetic paper was prepared by raw materials comprising 70 parts of the para-aramid fiber (5-6 mm), and 30 parts of the fibrid of para-aramid.

Herein the amounts of the ingredients were adjusted, but the preparation method of the synthetic paper is the same as that in Example 1. Mechanical properties of the synthetic paper are shown in Table 3.

TABLE 3
Mechanical properties of synthetic paper

| Mechanical property | unit | result |
|---|---|---|
| Mass | g/m² | 35 |
| Thickness | mm | 0.049 |
| Density | g/cm³ | 0.72 |
| Tensile strength | KN/m MD | 1.25 |
| Percentage elongation | % MD | 2.0 |

### Example 4

Synthetic paper was prepared by raw materials comprising 80 parts of the para-aramid fibers (5-6 mm), and 20 parts of the pulp of para-aramid.

Herein the preparation method of the synthetic paper is the same as that in Example 1. Mechanical properties of the synthetic paper are shown in Table 4.

TABLE 4
Mechanical properties of synthetic paper

| Mechanical property | unit | result |
|---|---|---|
| Mass | g/m² | 34.60 |
| Thickness | mm | 0.059 |
| Density | g/cm³ | 0.59 |
| Tensile strength | KN/m MD | 0.76 |
| Percentage elongation | % MD | 0.92 |

### Example 5

Synthetic paper was prepared by raw materials comprising 20 parts of the para-aramid fibers (5-6 mm), and 80 parts of the pulp of para-aramid.

Herein the preparation method of the synthetic paper is the same as that in Example 1. Mechanical properties of the synthetic paper are shown in Table 5.

TABLE 5
Mechanical properties of synthetic paper

| Mechanical property | unit | result |
|---|---|---|
| Mass | g/m² | 35.20 |
| Thickness | mm | 0.052 |
| Density | g/cm³ | 0.68 |
| Tensile strength | KN/m MD | 1.12 |
| Percentage elongation | % MD | 0.8 |

### Example 6

Synthetic paper was prepared by raw materials comprising 70 parts of the para-aramid fibers (5-6 mm), and 30 parts of the pulp of para-aramid.

Herein the preparation method of the synthetic paper is the same as that in Example 1. Mechanical properties of the synthetic paper are shown in Table 6.

TABLE 6
Mechanical properties of synthetic paper

| Mechanical property | unit | result |
|---|---|---|
| Mass | g/m² | 35 |
| Thickness | mm | 0.054 |
| Density | g/cm³ | 0.65 |
| Tensile strength | KN/m MD | 0.98 |
| Percentage elongation | % MD | 0.92 |

### Example 7

### Preparation of Pre-Pregs and Copper Clad Laminates

The pre-pregs and the copper clad laminates were prepared by the synthetic paper produced in Examples 1-6.

The synthetic paper was impregnated in an impregnating material (an epoxy resin, a polyimide resin, or a polytetrafluoroethylene resin) and then dried to yield the pre-preg. One or more layers (according to the requirements of the thickness) of the pre-preg were integrated with copper sheets at high temperature and high pressure to yield the copper clad laminate, which can be used to prepare different printed circuit boards according to different requirements.

The synthetic paper was impregnated in the epoxy resin, and was dried at the temperature of between 200 and 250° C. to yield the pre-preg; the pre-preg was cut into one or more layers, coated with copper, and laminated by using a laminating machine (the pressure was controlled at 30-50 kg and the temperature was controlled at between 200 and 250° C.) to yield the copper clad laminate.

Optionally, the synthetic paper was impregnated in the polyimide resin, and was dried at the temperature of between 200 and 250° C. to yield the pre-preg; the pre-preg was cut into one or more layers, coated with copper, and laminated by using the laminating machine (the pressure was controlled at 30-50 kg and the temperature was controlled at between 200 and 250° C.) to yield the copper clad laminate.

Optionally, the synthetic paper was impregnated in the polytetrafluoroethylene resin, and was dried at the temperature of between 280 and 380° C. to yield the pre-preg; the pre-preg was cut into one or more layers, coated with copper, and laminated by using the laminating machine (the pressure was controlled at 30-50 kg and the temperature was controlled at between 380 and 420° C.) to yield the copper clad laminate.

### Example 8

### Performance Measurement of Circuit Board Substrates

TABLE 7
Parameters comprising the linear coefficient of
thermal expansion (CTE), the dielectric constant (Dk),
and the dielectric loss (Df) of circuit board substrates prepared by
polytetrafluoroethylene resin-impregnated synthetic papers of
Examples 1-6

| Synthetic paper | CTE (ppm/° C.) | | Dk (1 GHz) | Df (1 GHz) |
|---|---|---|---|---|
| Example 1 | X-Y | 4-8 | 2.45 | 0.0015 |
| Example 2 | X-Y | 4-8 | 2.67 | 0.002 |
| Example 3 | X-Y | 4-8 | 2.40 | 0.001 |
| Example 4 | X-Y | 4-8 | 2.60 | 0.0018 |
| Example 5 | X-Y | 4-8 | 2.80 | 0.0017 |
| Example 6 | X-Y | 4-8 | 2.50 | 0.0015 |

TABLE 8
Parameters comprising the linear coefficient of
thermal expansion (CTE), the dielectric constant (Dk), and the
dielectric loss (Df) of circuit board substrates prepared by
epoxy resin-impregnated synthetic papers of Examples 1-6

| Synthetic paper | CTE (ppm/° C.) | | Dk (1 GHz) | Df (1 GHz) |
|---|---|---|---|---|
| Example 1 | X-Y | 5-8 | 3.40 | 0.012 |
| Example 2 | X-Y | 5-8 | 3.45 | 0.013 |
| Example 3 | X-Y | 5-8 | 3.40 | 0.011 |
| Example 4 | X-Y | 5-8 | 3.50 | 0.013 |
| Example 5 | X-Y | 5-8 | 3.50 | 0.013 |
| Example 6 | X-Y | 5-8 | 3.45 | 0.013 |
| Control group* | X-Y | 6-9 | — | 0.015 |

The control group* is a 55NT circuit board substrate produced by Arlon Company, and the synthetic paper for preparing the circuit board substrate comprises the para-aramid fibers and meta-aromatic polyamide fibers as a bonding agent. Parameters of the control group* are provided by Arlon Company.

TABLE 9
Parameters comprising the linear coefficient of
thermal expansion (CTE), the dielectric constant (Dk), and the
dielectric loss (Df) of circuit board substrates prepared by
polyimide resin-impregnated synthetic papers of Examples 1-6

| Synthetic paper | CTE (ppm/° C.) | | Dk (1 GHz) | Df (1 GHz) |
|---|---|---|---|---|
| Example 1 | X-Y | 5-8 | 3.25 | 0.011 |
| Example 2 | X-Y | 5-8 | 3.35 | 0.012 |
| Example 3 | X-Y | 5-8 | 3.25 | 0.011 |
| Example 4 | X-Y | 5-8 | 3.40 | 0.013 |
| Example 5 | X-Y | 5-8 | 3.40 | 0.012 |
| Example 6 | X-Y | 5-8 | 3.30 | 0.013 |
| Control group* | X-Y | 6-9 | 3.6 | 0.014 |

The control group* is a 85NT circuit board substrate produced by Arlon Company, and parameters of the control group* are provided by Arlon Company.

The specific gravity of the para-aromatic polyamide fibers is 1.44, and the specific gravity of glass fibers is 2.56, so the substrate made from the aramid fibers has a much lighter weight.

While particular embodiments of the invention have been shown and described, it will be obvious to those skilled in the art that changes and modifications may be made without departing from the invention in its broader aspects, and therefore, the aim in the appended claims is to cover all such changes and modifications as fall within the true spirit and scope of the invention.

The invention claimed is:

1. Synthetic paper, comprising:
between 10 and 90 wt. % of structural fibers; and
between 90 and 10 wt. % of bonding fibers;
wherein
the structural fibers are poly(p-phenylene telephthalamide) (PPTA) fibers having a fineness of between 1 and 2 d, and a length of between 3 and 10 mm;
the bonding fibers are fibrids or a pulp of the PPTA; and
the structural fibers and the bonding fibers are shaped by a wet-forming papermaking method, and hot rolled to form the synthetic paper.

2. The synthetic paper of claim 1, wherein the synthetic paper comprises 80 wt. % of the structural fibers and 20 wt. % of the bonding fibers.

3. The synthetic paper of claim 1, wherein the synthetic paper comprises 70 wt. % of the structural fibers and 30 wt. % of the bonding fibers.

4. The synthetic paper of claim 1, wherein the bonding fibers are fibrids of the PPTA having a beating degree of between 25 and 75° SR.

5. A pre-preg, comprising at least one layer of the synthetic paper of claim 1.

6. The pre-preg of claim 5, wherein
the pre-preg is prepared by employing the synthetic paper as a base material, and impregnating the base material in an impregnating material to produce the pre-preg; and
the impregnating material is selected from an epoxy resin, a polyimide resin, and a polytetrafluoroethylene resin.

7. The pre-preg of claim 6, wherein
the impregnating material is the polytetrafluoroethylene resin; and
a weight ratio between the impregnating material and the synthetic paper is between 47% and 55%.

8. The pre-preg of claim 5, wherein
the pre-preg has a linear coefficient of thermal expansion relative to X and Y axes in a plane of between 4 and 9 ppm/° C., a dielectric constant of between 2.4 and 3.5, and a dielectric loss of between 0.001 and 0.013.

9. A copper clad laminate (CCL), being prepared by coating copper on a surface of the pre-preg of claim 5.

10. A printed circuit board, comprising at least one layer of the synthetic paper of claim 1.

11. A printed circuit board, comprising the pre-preg of claim 5.

12. A printed circuit board, comprising the copper clad laminate of claim 9.
